(19) United States
(12) Patent Application Publication
(10) Pub. No.: US 2026/0203028 A1
(43) Pub. Date: Jul. 16, 2026

(54) METHOD AND APPARATUS WITH QUERY BASED FEW-SHOT PROMPT GENERATION

(71) Applicant: SAMSUNG ELECTRONICS CO., LTD., Suwon-si (KR)

(72) Inventors: Jongseok KIM, Suwon-si (KR); Jihye KIM, Suwon-si (KR); Do-Ha HWANG, Suwon-si (KR); Jaeyoon LEE, Suwon-si (KR)

(73) Assignee: SAMSUNG ELECTRONICS CO., LTD., Suwon-si (KR)

(21) Appl. No.: 19/274,885

(22) Filed: Jul. 21, 2025

(30) Foreign Application Priority Data
Jan. 10, 2025 (KR) 10-2025-0004280

(51) Int. Cl. G06F 8/35

(52) U.S. Cl. CPC G06F 8/35

(57) ABSTRACT

A processor-implemented method including searching for similar code, the similar code being similar to a query requesting code generation, generating a code description for the similar code by inputting the user query and the similar code to a first large language model (LLM), and generating a few-shot prompt including the query, the similar code, and the code description for the similar code.

### CROSS-REFERENCE TO RELATED APPLICATIONS

This application claims the benefit under 35 USC § 119(a) of Korean Patent Application No. 10-2025-0004280, filed on Jan. 10, 2025, in the Korean Intellectual Property Office, the entire disclosure of which is incorporated herein by reference for all purposes.

### BACKGROUND

### 1. Field

The following description relates to a method and apparatus with few-shot prompt generation, and more particularly to few-shot prompt generation based on a query.

### 2. Description of Related Art

Recent development of large language models (LLMs) has greatly improved software code writing capabilities of the latest high-performance models such as GPT-4 and LLama3. However, hardware description languages (HDLs) such as Verilog, Very High Speed Integrated Circuit (VHSIC) hardware description language (VHDL), and System Verilog have limited public data and high security levels unlike software languages, and thus, data collection is difficult. For example, based on a Stack V2 dataset, hardware code, such as Verilog (86 GB), VHDL (70 GB), and System Verilog (3.5 GB), makes up less than ⅓ of Python data volume (525 gigabyte (GB)), which is relatively small.

Most existing public LLMs are provided as pretrained and intuned models that train unlabeled data or data in the form of questions and answers. However, since the data used for training is often not disclosed, there is a limitation that training of a specific domain and instruction following capabilities are low.

Particularly, a typical HDL such as Verilog may have difficulty in generating instruction datasets because a code change history or relationship between specifications is not clearly connected, and it typically costs a lot to achieve high-level instruction following.

In languages such as Verilog, when external public data is insufficient, models trained using a domain-adaptive pretraining (DAPT) method may achieve performance close to GPT-4 in certain benchmarks despite the relatively small size or amount of public data. However, the models trained using the DAPT method have limited ability to understand and respond to various user instructions, which limits practical utilization.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

A processor-implemented method including searching for similar code, the similar code being similar to a query requesting code generation, generating a code description for the similar code by inputting the user query and the similar code to a first large language model (LLM), and generating a few-shot prompt including the query, the similar code, and the code description for the similar code.

The method may include generating code for the query by inputting the few-shot prompt to a second LLM.

The second LLM may be trained for one of a preset programming language or a preset domain.

The first LLM may be a general purpose LLM not limited to the preset programming language or the preset domain.

The searching for the similar code may include searching for the similar code corresponding to the query through a retriever.

The retriever may be configured to search for the similar code corresponding to the query in a hardware technology design language code database.

The first LLM may be a general purpose LLM.

The few-shot prompt may include input/output port information corresponding to the query.

In a general aspect, here is provided a non-transitory computer-readable storage medium storing instructions that, when executed by a processor, cause the processor to perform the method.

In a general aspect, here is provided an electronic device including one or more processors, a memory configured to store instructions, and, when executed by the one or more processors, the instructions cause the electronic device to perform searching for similar code similar to a received query for code generation, generating a code description for the similar code by inputting the received query and the similar code to a first large language model (LLM), and generating a few-shot prompt including the received query, the similar code, and the code description for the similar code.

The electronic device may further perform generating code for the received query by inputting the few-shot prompt to a second LLM.

The second LLM may be trained for a preset programming language or a preset domain.

The first LLM may be a general purpose LLM not limited to the preset programming language or the preset domain.

The electronic device may further perform searching for the similar code corresponding to the received query through a retriever.

The retriever may be configured to search for the similar code corresponding to the received query in a hardware technology design language code database.

The first LLM may be a general purpose LLM.

The few-shot prompt may include input/output ports information corresponding to the received query.

In a general aspect, here is provided a system for generating a few-shot prompt including a retriever configured to search for similar code for an input query, a first large language model (LLM) configured to generate a code description corresponding to an input code of the input query, and a few-shot prompt generation apparatus configured to, in response to receiving the input query requesting code generation, search for similar code similar to the user query through the retriever, receive a code description for the similar code from the first LLM by inputting the input query and the similar code to the first LLM, and generate a few-shot prompt including the user query, the similar code, and the code description for the similar code.

The system may include a second LLM configured to generate code for the input query, and the few-shot prompt generation apparatus may be configured to receive code for the input query from the second LLM by inputting the few-shot prompt to the second LLM.

The retriever may be configured to search for the similar code corresponding to the input query in a hardware technology design language code database.

Other features and aspects will be apparent from the following detailed description, the drawings, and the claims.

### BRIEF DESCRIPTION OF THE DRAWINGS

FIG. 1 illustrates an example system with query based few-shot prompt generation according to one or more embodiments.

FIG. 2 illustrates an example electronic apparatus with query based few-shot prompt generation according to one or more embodiments.

FIG. 3 illustrates an example method with query based few-shot prompt generation according to one or more embodiments.

FIG. 4 illustrates an example search for similar code for a user query with a few-shot prompt generation apparatus according to one or more embodiments.

FIG. 5 illustrates an example generating of a description corresponding to similar code with a few-shot prompt generation apparatus according to one or more embodiments.

FIG. 6 illustrates an example generating of a few-shot prompt in a few-shot prompt generation apparatus according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

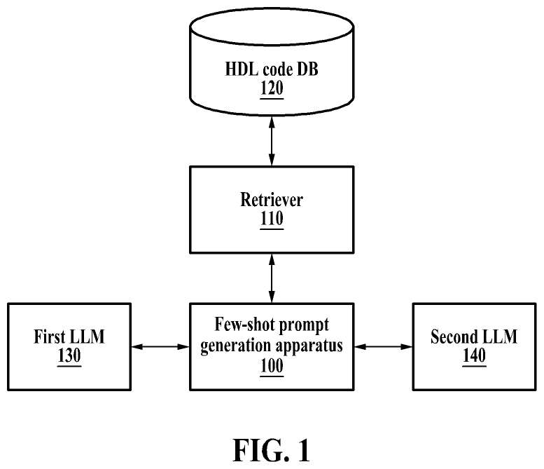

Hereinafter, a method and apparatus for generating a few-shot prompt based on a query according to an example of the present invention are described in detail with reference to FIGS. 1 to 6.

FIG. 1 illustrates an example system with query based few-shot prompt generation according to one or more embodiments.

Referring to FIG. 1, in a non-limiting example, the system may include a few-shot prompt generation apparatus 100, a retriever 110, a hardware description language (HDL) code database (DB) 120, a first large language model (LLM) 130, and a second LLM 140.

In an example, the few-shot prompt generation apparatus 100 may generate a few-shot prompt corresponding to a user query that generates code using the retriever 110 and the first LLM 130. For example, few-shot prompt generation may refer to models that are trained with only a small number of training examples. As the data available for training related to software development is often not disclosed or available, specific domains and programming language examples may not be as detailed as training data used for other LLM applications.

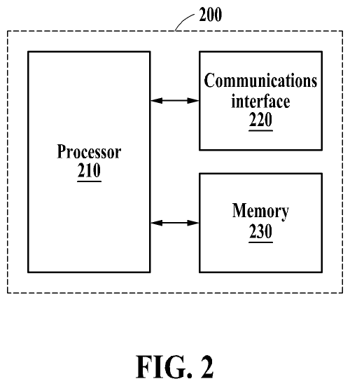

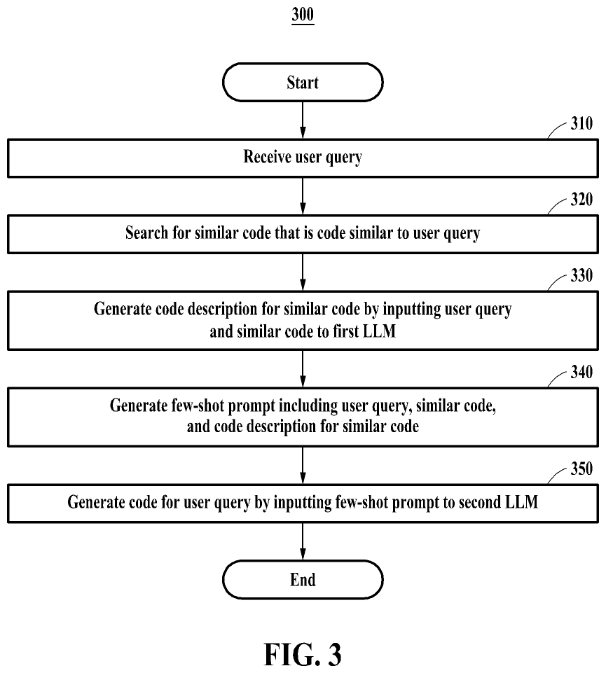

The few-shot prompt generation apparatus 100 may provide the generated few-shot prompt to a second LLM to generate code corresponding to the user query. The few-shot prompt generation apparatus 100 is described in greater detail below with reference to FIGS. 2 and 3.

In an example, the retriever 110 may search the HDL code DB 120 for similar code that is most relevant to the user query. The retriever 110 may search the HDL code DB 120 for the similar code that is most relevant to the user query but may also perform a search through the Internet for the similar code.

The HDL code DB 120 may be a database for supporting hardware design, simulation, verification, and optimization and may systematically store, manage, and search code written in an HDL and related data. The HDL may be mainly used for hardware design, and representative examples include Verilog and Very High Speed Integrated Circuit (VHSIC) HDL (VHDL)

The first LLM 130 may include tens of billions to trillions of parameters and may be a general-purpose model that is trained with a wide range of data and may perform various tasks. The first LLM 130 may be a high-end LLM that is trained based on a wide range of data, may handle tasks in various fields (e.g., translation, summarization, code generation, and creative writing), and may not be limited to a particular domain. Examples of the first LLM 130 may include OpenAI's GPT series, Google's PaLM, and Anthropic's Claude.

In an example, the second LLM 140 may be a domain-adapted code LLM, which is a language model optimized for a code task in a specific domain (e.g., software development, a specific programming language, and a specific industry field).

FIG. 2 illustrates an example electronic apparatus with query based few-shot prompt generation according to one or more embodiments.

Referring to FIG. 2, in a non-limiting example, the electronic apparatus 200 may include a processor 210, a communications interface 220, and a memory 230. In an example, the electronic apparatus 200 may be or perform the operations of the few-shot prompt generation apparatus 100, and the electronic device 200 may include a communication device, such as a smartphone and the like, a vehicle, such as an automobile and the like, a display device, such as a TV and the like, a consumer electronic apparatus, such as a washing machine and the like, a manufacturing apparatus, and the like.

In an example, the communicator 220 may be a communication interface device including a receiver and a transmitter that transmits and receives data by wire or wirelessly. The communicator 220 may communicate with the retriever 110, the first LLM 130, and the second LLM 140.

The memory 230 may store an operating system, application program, and storage data for controlling the overall operation of the electronic apparatus 200 (e.g., the few-shot prompt generation apparatus 100). In addition, the memory 230 may store applications, user queries, searched similar code, descriptions corresponding to generated similar code, and few-shot prompts, according to the present disclosure.

The processor 210 may control operations of the electronic apparatus 200 and thus the few-shot prompt generation apparatus 100 of FIGS. 1 and 2 by executing instructions stored in the memory 230. The memory 230 may include computer-readable instructions. The processor 210 may be configured to execute computer-readable instructions, such as those stored in the memory 230, and through execution of the computer-readable instructions, the processor 210 is configured to perform one or more, or any combination, of the operations and/or methods described herein. The memory 230 may be a volatile or nonvolatile memory.

The processor 210 may be configured to execute programs or applications to configure the processor 210 to control the electronic apparatus 200 to perform one or more or all operations and/or methods involving the few-shot prompt generation, and may include any one or a combination of two or more of, for example, a central processing unit (CPU), a graphic processing unit (GPU), a neural processing unit (NPU) and tensor processing units (TPUs), but is not limited to the above-described examples.

The processor 210, when receiving a user query for generating code from a user, ay search for similar code, which is code similar to the user query, through the retriever 110.

The processor 210, by executing the instructions stored in the memory 230, may generate a code description for the similar code by inputting the user query and the similar code to the first LLM 130 and may generate a few-shot prompt including the user query, the similar code, and the code description for the similar code. Here, the few-shot prompt may further include information about input/output ports corresponding to the user query.

The processor 210, by executing the instructions stored in the memory 230, may input the few-shot prompt to the second LLM 140 to generate code for the user query.

Hereinafter, a method according to the present disclosure configured as described above is described in greater detail with reference to the drawings below.

FIG. 3 illustrates an example method with query based few-shot prompt generation according to one or more embodiments.

Referring to FIG. 3, in a non-limiting example, method 300 may include operation 310 where an electronic apparatus (e.g., electronic apparatus 200 and/or few-shot prompt generation apparatus 100) may receive a user query for generating code from a user.

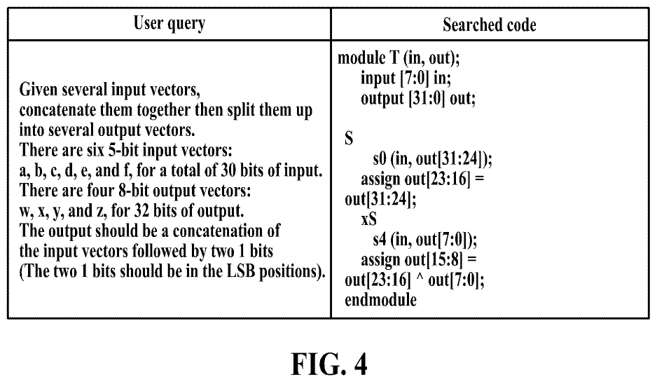

In an example, in operation 320, the electronic apparatus (e.g., electronic apparatus 200 and/or few-shot prompt generation apparatus 100) may search for similar code that is code similar to the user query. In operation 320, the electronic apparatus may search for the similar code corresponding to the user query through a retriever (e.g., the retriever 110). Here, the retriever may search for the similar code corresponding to the user query in a database (e.g., the HDL code DB 120). Here, the user query and the similar code corresponding to the user query may be confirmed as described in greater detail below with respect to FIG. 4.

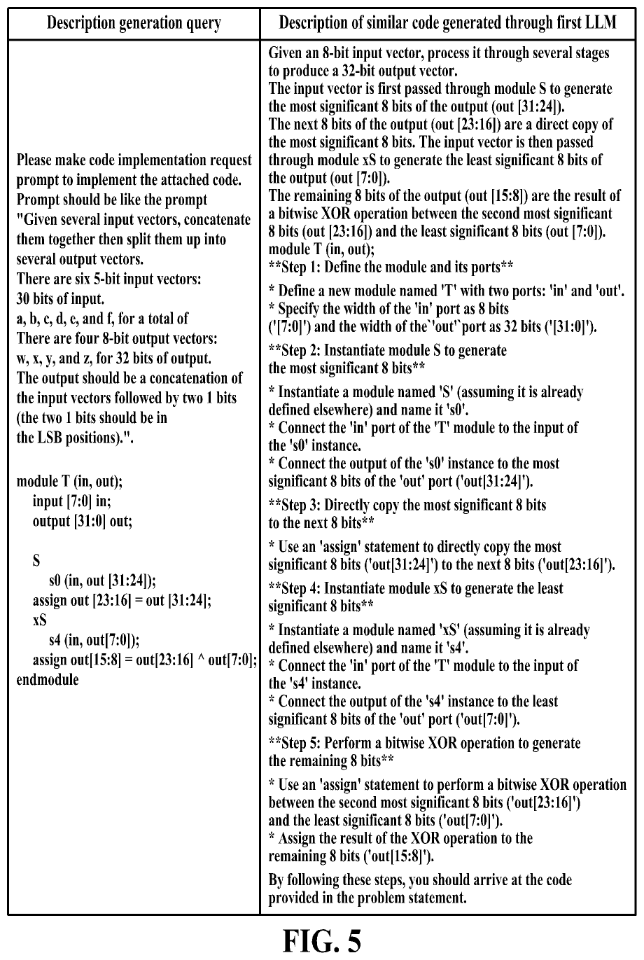

In an example, in operation 330, the electronic device (e.g., electronic apparatus 200 and/or few-shot prompt generation apparatus 100) may input the user query and the similar code to a first LLM (e.g., the first LLM 130) to generate a code description for the similar code. Here, the first LLM may be a general-purpose model that may perform various tasks. For example, the first LLM may be a high-end LLM that is not limited to a domain, trained based on a wide range of data, and may handle tasks in various fields (e.g., translation, summarization, code generation, and creative writing). Here, the code description for the similar code may be confirmed as described in greater detail below with respect to FIG. 5.

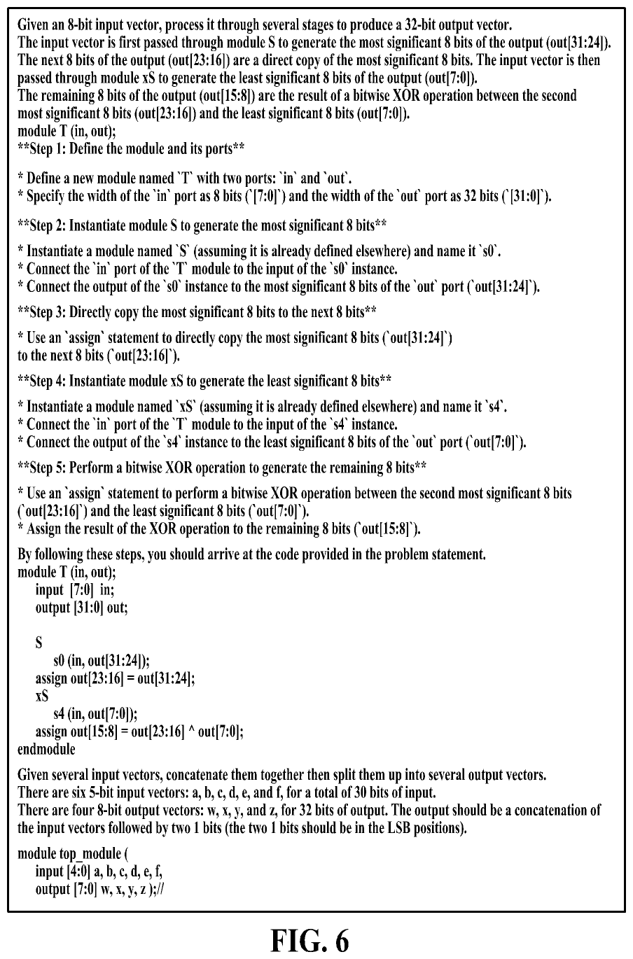

In an example, in operation 340, the electronic device (e.g., electronic apparatus 200 and/or few-shot prompt generation apparatus 100) may generate a few-shot prompt including the user query, the similar code, and the code description for the similar code. Here, the few-shot prompt may further include information about input/output ports corresponding to the user query. Here, the few-shot prompt may be confirmed as described in greater detail below with respect to FIG. 6.

In an example, in operation 350, the electronic apparatus (e.g., the electronic apparatus 200 and/or few-shot prompt generation apparatus 100) may generate code for the user query by inputting the few-shot prompt to the second LLM (e.g., second LLM 140).

In an example, the second LLM may be a domain-adapted code LLM, which is a language model optimized for a code task in a specific domain (e.g., software development, a specific programming language, and a specific industry field). Furthermore, the first LLM (e.g., first LLM 130) and the second LLM may be configured to be the same LLM.

In an example, the electronic apparatus performing method 300 may further enhance the ability to generate the code corresponding to the user query by providing the second LLM with the few-shot prompt including the user query, the similar code, and the code description for the similar code.

FIG. 4 illustrates an example search for similar code for a user query with a few-shot prompt generation apparatus according to one or more embodiments.

Referring to FIG. 4, in a non-limiting example, the retriever 110 may search the HDL code DB 120 for a user query “Given several input vectors, concatenate them together then split them up into several output vectors. There are six 5-bit input vectors: a, b, c, d, e, and f, for a total of 30 bits of input. There are four 8-bit output vectors: w, x, y, and z, for 32 bits of output. The output should be a concatenation of the input vectors followed by two 1 bits (the two 1 bits should be in the LSB positions).” and may output the following similar code as shown in Table 1.

TABLE 1

```
module T (in, out);
  input [7:0] in;
  output [31:0] out;
  S
    s0 (in, out[31:24]);
  assign out[23:16] = out[31:24];
  xS
    s4 (in, out[7:0]);
  assign out[15:8] = out[23:16] \hat{ } out[7:0];
endmodule
```

FIG. 5 illustrates an example generating of a description corresponding to similar code with a few-shot prompt generation apparatus according to one or more embodiments.

Referring to FIG. 5, in a non-limiting example, when the first LLM 130 receives the user query and the similar code of FIG. 4 as input, the first LLM 130 may analyze the user query and the similar code and may output a description of the similar code as follows and as illustrated in Table 2.

Given an 8-bit input vector, process it through several stages to produce a 32-bit output vector. The input vector is first passed through module S to generate the most significant 8 bits of the output (out[31:24]). The next 8 bits of the output (out[23:16]) are a direct copy of the most significant 8 bits. The input vector is then passed through module xS to generate the least significant 8 bits of the output (out[7:0]). The remaining 8 bits of the output (out[15:8]) are the result of a bitwise XOR operation between the second most significant 8 bits (out[23:16]) and the least significant 8 bits (out[7:0]).

TABLE 2
module T (in, out);
**Step 1: Define the module and its ports**
* Define a new module named ‘T’ with two ports: ‘in’ and ‘out’.
* Specify the width of the ‘in’ port as 8 bits (‘[7:0]’) and the width of the
‘out’ port as 32 bits (‘[31:0]’).
**Step 2: Instantiate module S to generate the most significant 8 bits**
* Instantiate a module named ‘S’ (assuming it is already defined
elsewhere) and name it ‘s0’.
* Connect the ‘in’ port of the ‘T’ module to the input of the ‘s0’ instance.
* Connect the output of the ‘s0’ instance to the most significant 8 bits of
the ‘out’ port (‘out[31:24]’).
**Step 3: Directly copy the most significant 8 bits to the next 8 bits**
* Use an ‘assign’ statement to directly copy the most significant 8 bits
(‘out[31:24]’) to the next 8 bits (‘out[23:16]’).
**Step 4: Instantiate module xS to generate the least significant 8 bits**
* Instantiate a module named ‘xS’ (assuming it is already defined
elsewhere) and name it ‘s4’.
* Connect the ‘in' port of the ‘T’ module to the input of the ‘s4’ instance.
* Connect the output of the ‘s4’ instance to the least significant 8 bits of
the ‘out’ port (‘out[7:0]’).
**Step 5: Perform a bitwise XOR operation to generate the remaining
8 bits**
* Use an ‘assign’ statement to perform a bitwise XOR operation between
the second most significant 8 bits (‘out[23:16]’) and the least significant
8 bits (‘out[7:0]’).

FIG. 6 illustrates an example generating of a few-shot prompt in a few-shot prompt generation apparatus according to one or more embodiments.

Referring to FIG. 6, in a non-limiting example, the few-shot prompt generation apparatus 100 may generate a few-shot prompt that includes all the description of the similar code of FIG. 5 together with the user query and the similar code of FIG. 4. Here, the few-shot prompt generation apparatus 100 may add information about input/output ports corresponding to the user query as in the following example in Table 3.

TABLE 3

```
module top_module (
  input [4:0] a, b, c, d, e, f,
  output [7:0] w, x, y, z );//
```

The neural networks, electronic devices, processors, memories, processing elements, few-shot prompt generating apparatus 100, retriever 110, HDL code DB 120, first LLM 130, second LLM 140, electronic apparatus 200, processor 210, memory 230, and communication interface 220 described herein and disclosed herein described with respect to FIGS. 1-6 are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-6 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method, the method comprising:
searching for similar code, the similar code being similar to a query requesting code generation;
generating a code description for the similar code by inputting the user query and the similar code to a first large language model (LLM); and
generating a few-shot prompt comprising the query, the similar code, and the code description for the similar code.

2. The method of claim 1, further comprising:
generating code for the query by inputting the few-shot prompt to a second LLM.

3. The method of claim 2, wherein the second LLM is trained for one of a preset programming language or a preset domain.

4. The method of claim 3, wherein the first LLM is a general purpose LLM not limited to the preset programming language or the preset domain.

5. The method of claim 1, wherein the searching for the similar code comprises:
searching for the similar code corresponding to the query through a retriever.

6. The method of claim 3, wherein the retriever is configured to search for the similar code corresponding to the query in a hardware technology design language code database.

7. The method of claim 1, wherein the first LLM is a general purpose LLM.

8. The method of claim 1, wherein the few-shot prompt further comprises input/output port information corresponding to the query.

9. A non-transitory computer-readable storage medium storing instructions that, when executed by a processor, cause the processor to perform the method of claim 1.

10. An electronic device comprising:
one or more processors; and
a memory configured to store instructions,
wherein, when executed by the one or more processors, the instructions cause the electronic device to perform:
searching for similar code similar to a received query for code generation;
generating a code description for the similar code by inputting the received query and the similar code to a first large language model (LLM); and
generating a few-shot prompt comprising the received query, the similar code, and the code description for the similar code.

11. The electronic device of claim 10, wherein the instructions, when executed by the one or more processors, cause the electronic device to further perform generating code for the received query by inputting the few-shot prompt to a second LLM.

12. The electronic device of claim 11, wherein the second LLM is trained for a preset programming language or a preset domain.

13. The electronic device of claim 12, wherein the first LLM is a general purpose LLM not limited to the preset programming language or the preset domain.

14. The electronic device of claim 10, wherein the instructions, when executed by the one or more processors, cause the electronic device to further perform searching for the similar code corresponding to the received query through a retriever.

15. The electronic device of claim 14, wherein the retriever is configured to search for the similar code corresponding to the received query in a hardware technology design language code database.

16. The electronic device of claim 10, wherein the first LLM is a general purpose LLM.

17. The electronic device of claim 10, wherein the few-shot prompt further comprises input/output ports information corresponding to the received query.

18. A system for generating a few-shot prompt, the system comprising:
a retriever configured to search for similar code for an input query;
a first large language model (LLM) configured to generate a code description corresponding to an input code of the input query; and
a few-shot prompt generation apparatus configured to:
in response to receiving the input query requesting code generation, search for similar code similar to the user query through the retriever;
receive a code description for the similar code from the first LLM by inputting the input query and the similar code to the first LLM; and
generate a few-shot prompt comprising the user query, the similar code, and the code description for the similar code.

19. The system of claim 18, further comprising:
a second LLM configured to generate code for the input query,
wherein the few-shot prompt generation apparatus is configured to receive code for the input query from the second LLM by inputting the few-shot prompt to the second LLM.

20. The system of claim 18, wherein the retriever is configured to search for the similar code corresponding to the input query in a hardware technology design language code database.
